(19) United States
(12) Patent Application Publication
(10) Pub. No.: US 2024/0184101 A1
(43) Pub. Date: Jun. 6, 2024

(54) DRIVE ELEMENT

(71) Applicant: Panasonic Intellectual Property Management Co., Ltd., Osaka (JP)

(72) Inventor: Shoji OKAMOTO, Osaka (JP)

(21) Appl. No.: 18/440,521

(22) Filed: Feb. 13, 2024

Related U.S. Application Data
(63) Continuation of application No. PCT/JP2022/014164, filed on Mar. 24, 2022.

(30) Foreign Application Priority Data
Aug. 19, 2021 (JP) 2021-134027

(51) Int. Cl. G02B 26/10; H02N 2/10

(52) U.S. Cl. CPC G02B 26/105; H02N 2/108

(57) ABSTRACT

A drive element includes: a fixing part; an oscillating plate connected to the fixing part and having a movable part configured to rotate about a rotation axis; and a drive part placed on the oscillating plate and configured to drive the oscillating plate. The oscillating plate contains a first material having a positive linear expansion coefficient and a second material having a negative linear expansion coefficient.

### CROSS REFERENCE TO RELATED APPLICATION

This application is a continuation of International Application No. PCT/JP2022/014164 filed on Mar. 24, 2022, entitled “DRIVE ELEMENT”, which claims priority under 35 U.S.C. Section 119 of Japanese Patent Application No. 2021-134027 filed on Aug. 19, 2021, entitled “DRIVE ELEMENT”. The disclosures of the above applications are incorporated herein by reference.

### BACKGROUND OF THE INVENTION

### Field of the Invention

The present invention relates to a drive element that rotates a movable part about a rotation axis.

### Description of Related Art

A drive element that rotates a movable part about a rotation axis has been known. In this type of drive element, for example, a mirror is placed on the movable part. Accordingly, scanning can be performed with a beam incident on the mirror as the mirror rotates. That is, in this configuration, the drive element and the mirror constitute a light deflector.

International Publication No. WO2009/130902 describes a meandering oscillator including: a plurality of oscillating plates each composed of a silicon substrate; and a piezoelectric transducer placed on each oscillating plate.

In the above drive element, when the environmental temperature around the drive element changes, each oscillating plate expands or contracts, and the resonance frequency of each oscillating plate changes. Accordingly, the resonance frequency of the entire drive element changes, so that it is difficult to rotate the movable part at an appropriate vibrating angle.

### SUMMARY OF THE INVENTION

A drive element according to a main aspect of the present invention includes: a fixing part; an oscillating plate connected to the fixing part and having a movable part configured to rotate about a rotation axis; and a drive part placed on the oscillating plate and configured to drive the oscillating plate. The oscillating plate contains a first material having a positive linear expansion coefficient and a second material having a negative linear expansion coefficient.

In the drive element according to this aspect, since the signs of the linear expansion coefficients of the first material and the second material are opposite to each other, when the environmental temperature around the drive element changes, a change in the resonance frequency of the oscillating plate due to the first material and a change in the resonance frequency of the oscillating plate due to the second material act on the oscillating plate in directions opposite to each other. Therefore, variation of the resonance frequency of the entire oscillating plate is suppressed by these opposing actions. Accordingly, variation of the resonance frequency of the drive element due to temperature change can be suppressed.

The effects and the significance of the present invention will be further clarified by the description of the embodiments below. However, the embodiments below are merely examples for implementing the present invention. The present invention is not limited to the description of the embodiments below in any way.

### BRIEF DESCRIPTION OF THE DRAWINGS

FIG. 1 is a plan view schematically showing a configuration of a drive element according to Embodiment 1;

FIG. 2A is a diagram schematically showing a cross-section of a lamination structure composed of an oscillating plate and a drive part or a wiring part according to Embodiment 1;

FIG. 2B is a diagram schematically showing a cross-section of a lamination structure composed of a fixing part and the wiring part according to Embodiment 1;

FIG. 3A to FIG. 3D are each a diagram for describing a procedure for forming the drive element according to Embodiment 1;

FIG. 4A to FIG. 4D are each a diagram for describing a procedure for forming the drive element according to Embodiment 1;

FIG. 5A is a perspective view schematically showing a configuration of a structure composed of a simple support beam;

FIG. 5B is a graph showing a relationship between the frequency of a drive voltage and the vibrating angle of a mirror in the case where the oscillating plate is made of only silicon;

FIG. 6A is a perspective view schematically showing a configuration of an oscillating plate composed of a cantilever beam used in simulation, according to Embodiment 1;

FIG. 6B is a graph showing simulation results according to Embodiment 1;

FIG. 7A is a cross-sectional view schematically showing a configuration of an oscillating plate composed of a cantilever beam used in simulation, according to Embodiment 1;

FIG. 7B is a graph showing simulation results according to Embodiment 1;

FIG. 8A is a diagram showing a relationship between a temperature coefficient of the resonance frequency of the oscillating plate, a temperature range of the oscillating plate, and a change width of the resonance frequency of the oscillating plate according to Embodiment 1;

FIG. 8B is a graph showing a relationship between the frequency of a drive voltage and a vibrating angle of the mirror according to Embodiment 1;

FIG. 9A and FIG. 9B are diagrams schematically showing cross-sections of oscillating plates and fixing parts according to a comparative example and Embodiment 1, respectively;

FIG. 10A is a diagram schematically showing a cross-section of a lamination structure composed of an oscillating plate and a drive part or a wiring part according to Modification 1 of Embodiment 1;

FIG. 10B is a diagram schematically showing a cross-section of a lamination structure composed of a fixing part and the wiring part according to Modification 1 of Embodiment 1;

FIG. 11A to FIG. 11D are each a diagram for describing a procedure for forming a drive element according to Modification 1 of Embodiment 1;

FIG. 12A to FIG. 12C are each a diagram for describing a procedure for forming the drive element according to Modification 1 of Embodiment 1;

FIG. 13 is a plan view schematically showing a configuration of a drive element according to Modification 2 of Embodiment 1;

FIG. 14 is a plan view schematically showing a configuration of the drive element according to Embodiment 2; and

FIG. 15 is a plan view schematically showing a configuration of a drive element according to a modification of Embodiment 2.

It should be noted that the drawings are solely for description and do not limit the scope of the present invention by any degree.

### DETAILED DESCRIPTION

Hereinafter, embodiments of the present invention will be described with reference to the drawings. For convenience, in each drawing, X, Y, and Z axes that are orthogonal to each other are additionally shown. The Z-axis positive direction is the vertical upward direction.

### Embodiment 1

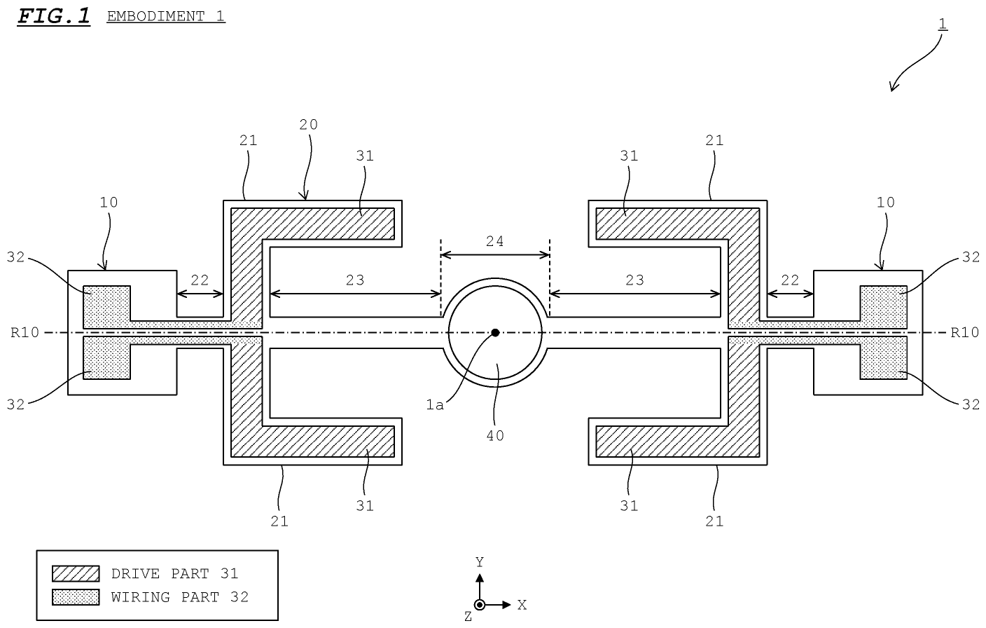

FIG. 1 is a plan view schematically showing a configuration of a drive element 1.

The drive element 1 includes a pair of fixing parts 10, an oscillating plate 20, four drive parts 31, four wiring parts 32, and a mirror 40. The drive element 1 is configured to be symmetrical in the X-axis direction and the Y-axis direction about a center 1a. A movable part 24 is provided at the center of the drive element 1, and the movable part 24 rotates about a rotation axis R10 which passes through the center 1a and extends in the X-axis direction.

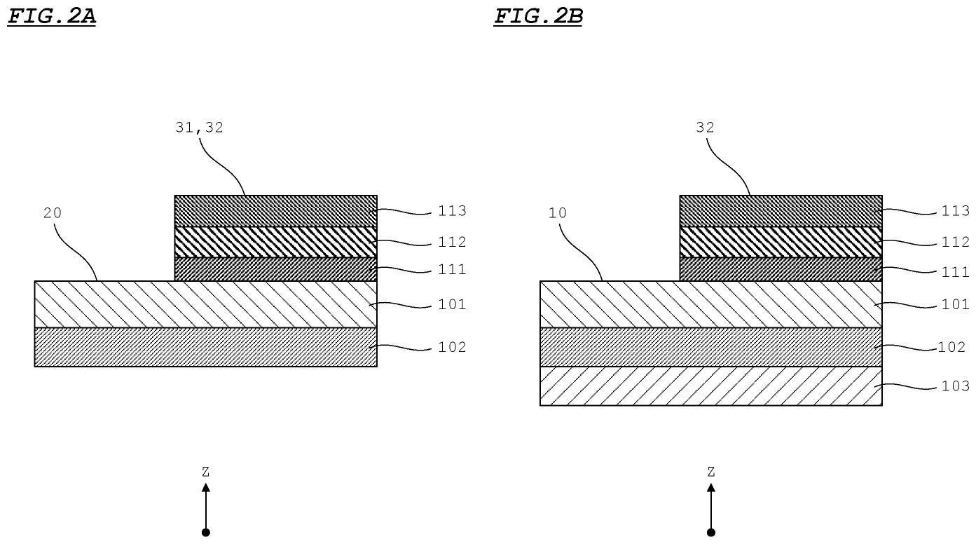

The pair of fixing parts 10 are aligned in the direction of the rotation axis R10. When the drive element 1 is installed, the surface on the Z-axis negative side of each fixing part 10 (the surface on the Z-axis negative side of a fixing layer 103 in FIG. 2B) is installed on a package substrate or the like using an adhesive.

The oscillating plate 20 includes four arm parts 21, two connection parts 22, two connection parts 23, and the movable part 24. The oscillating plate 20 has a tuning fork shape. That is, the two arm parts 21 on the X-axis positive side from the movable part 24 have a tuning fork shape in a plan view, and the two arm parts 21 on the X-axis negative side from the movable part 24 have a tuning fork shape in a plan view. These two tuning fork shapes face each other in the X-axis direction, thereby defining the shape of the oscillating plate 20.

Two arm parts 21 aligned in the Y-axis direction are configured to be symmetrical to each other about the rotation axis R10. Each arm part 21 has an L-shape in a plan view. The two arm parts 21 aligned in the Y-axis direction are connected to the fixing part 10 via the connection part 22, and are connected to the movable part 24 via the connection part 23. The connection parts 22 and 23 extend along the rotation axis R10.

The mirror 40 is placed on the surface on the Z-axis positive side of the movable part 24. The movable part 24 and the mirror 40 have a circular shape centered on the center 1a in a plan view. A rib (not shown) for suppressing bending of the movable part 24 is formed on the surface on the Z-axis negative side of the movable part 24.

The four drive parts 31 are placed on the surfaces on the Z-axis positive side of the four arm parts 21, respectively. Each drive part 31 is a so-called piezoelectric transducer. A piezoelectric transducer is sometimes called piezoelectric actuator. When a drive voltage is applied to each drive part 31, the arm part 21 on which the drive part 31 is placed is driven. The four wiring parts 32 are placed on the surfaces on the Z-axis positive side of the oscillating plate 20 and the fixing parts 10. An end portion on the inner side (center 1a side) of each wiring part 32 is connected to the drive part 31, and an end portion on the outer side of each wiring part 32 is connected to an external power supply or the like at the fixing part 10. The wiring part 32 supplies the drive voltage to the drive part 31.

When the oscillating plate 20 is driven, voltages having opposite phases are applied to the drive parts 31 on two arm parts 21, which are aligned in the Y-axis direction, such that these two arm parts 21 vibrate in opposite directions in the Z-axis direction. In addition, voltages having the same phase are applied to the drive parts 31 on two arm parts 21, which are aligned in the X-axis direction, such that these two arm parts 21 vibrate in the same direction in the Z-axis direction. At this time, drive voltages are applied to the four drive parts 31 at a frequency equal to the resonance frequency of the oscillating plate 20 at a reference temperature.

Accordingly, the movable part 24 and the mirror 40 rotate about the rotation axis R10, so that the direction of light incident on the mirror 40 is changed in accordance with the rotation angle of the mirror 40.

FIG. 2A is a diagram schematically showing a cross-section of a lamination structure composed of the oscillating plate 20 and the drive part 31 or the wiring part 32.

The oscillating plate 20 includes a first layer 101 and a second layer 102 placed on the surface on the Z-axis negative side of the first layer 101. The first layer 101 is made of silicon (Si), and the second layer 102 is made of scandium fluoride (ScF₃).

The drive part 31 and the wiring part 32 have the same lamination structure as each other and are formed integrally. The drive part 31 and the wiring part 32 are placed on the surface on the Z-axis positive side of the oscillating plate 20. In the drive part 31 and the wiring part 32, a lower electrode 111, a piezoelectric layer 112, and an upper electrode 113 are formed in this order in the Z-axis positive direction. The lower electrode 111 is made of platinum (Pt), the piezoelectric layer 112 is made of PZT (lead zirconate titanate: Pb (Zr, Ti)O₃), and the upper electrode 113 is made of gold (Au).

As shown in FIG. 2A, the piezoelectric layer 112 is placed between the lower electrode 111 and the upper electrode 113, and thus also serves as a dielectric body that insulates the lower electrode 111 and the upper electrode 113 from each other.

FIG. 2B is a diagram schematically showing a cross-section of a lamination structure composed of the fixing part 10 and the wiring part 32.

The first layer 101 and the second layer 102 shown in FIG. 2A extend to the fixing part 10. That is, the first layer 101 and the second layer 102 are integrally formed in the entire fixing part 10 and the entire oscillating plate 20. The fixing part 10 further includes the fixing layer 103 placed on the surface on the Z-axis negative side of the second layer 102.

The wiring part 32 shown in FIG. 2A extends to the fixing part 10. That is, the wiring part 32 on the fixing part 10 and the wiring part 32 on the oscillating plate 20 are integrally formed.

In the fixing part 10, for example, when the lower electrode 111 of the wiring part 32 is connected to a ground, and a drive voltage is applied to the upper electrode 113 of the wiring part 32, the piezoelectric layer 112 of the drive part 31 connected to the wiring part 32 becomes deformed. Accordingly, the oscillating plate 20 is driven, and the movable part 24 and the mirror 40 (see FIG. 1) rotate about the rotation axis R10.

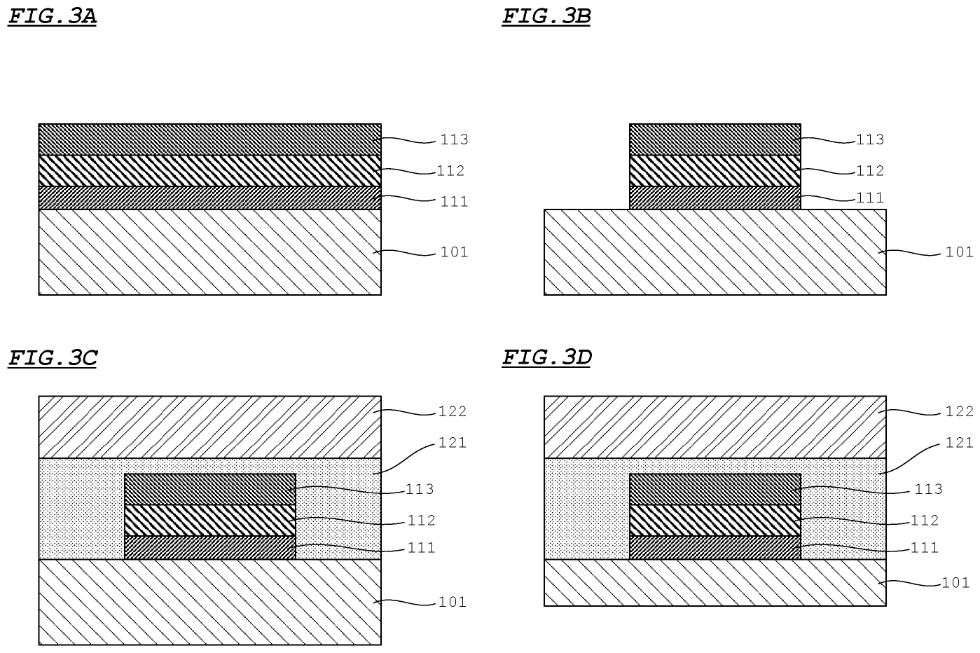

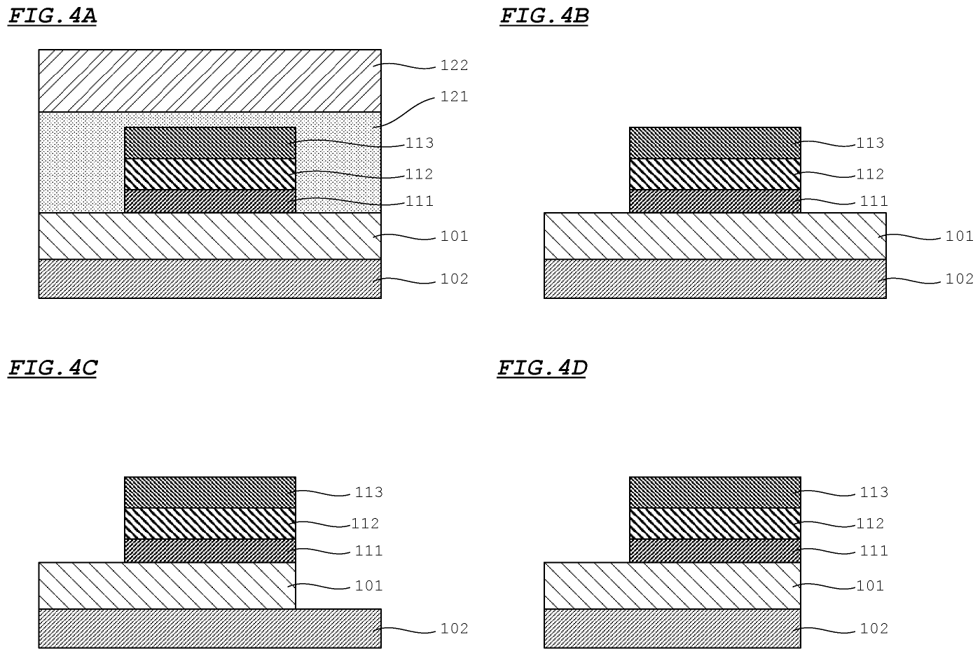

Next, a procedure for forming the drive element 1 will be described with reference to cross-sectional views in FIG. 3A to FIG. 4D.

As shown in FIG. 3A, the lower electrode 111 (Pt), the piezoelectric layer 112 (PZT), and the upper electrode 113 (Au) are formed in this order by sputtering on the upper surface of the first layer 101 (Si substrate).

Subsequently, as shown in FIG. 3B, the lower electrode 111, the piezoelectric layer 112, and the upper electrode 113 are removed by etching such that the lower electrode 111, the piezoelectric layer 112, and the upper electrode 113 remain in a region corresponding to each drive part 31 and each wiring part 32.

Subsequently, as shown in FIG. 3C, a support substrate 122 made of silicon (Si) is attached above the first layer 101, the lower electrode 111, the piezoelectric layer 112, and the upper electrode 113 with an adhesive 121 therebetween.

Subsequently, as shown in FIG. 3D, the lower surface of the first layer 101 is cut such that the first layer 101 has a desired thickness.

Subsequently, as shown in FIG. 4A, the second layer 102 (scandium fluoride substrate) is attached to the lower surface of the first layer 101. In attaching the second layer 102, the second layer 102 may be directly attached and fixed to the lower surface of the first layer 101, or an adhesive may be applied to the lower surface of the first layer 101, and the second layer 102 may be attached thereto.

Subsequently, as shown in FIG. 4B, the adhesive 121 and the support substrate 122 are removed.

Subsequently, as shown in FIG. 4C, the first layer 101 is cut into a desired shape by etching. Accordingly, in a plan view, the shape of the first layer 101 is made into a shape obtained by combining the fixing parts 10 and the oscillating plate 20 shown in FIG. 1.

Subsequently, as shown in FIG. 4D, the second layer 102 is cut into the same shape as the first layer 101 in a plan view by etching.

Thereafter, the fixing layer 103 is attached to the lower surface of the second layer 102 corresponding to each fixing part 10. In addition, a rib, made of silicon (Si), for maintaining the strength of the movable part 24 is installed on the lower surface of the second layer 102 corresponding to the movable part 24, and the mirror 40 is placed on the upper surface of the first layer 101 corresponding to the movable part 24. Thus, the drive element 1 is completed.

Meanwhile, in the configuration in FIG. 1, in the case where the oscillating plate 20 is composed of only a layer made of silicon (Si), when the environmental temperature around the drive element 1 changes, the resonance frequency of the oscillating plate 20 changes with the change in the environmental temperature. Accordingly, the resonance frequency of the entire drive element 1 changes, so that it is difficult to rotate the movable part 24 at an appropriate vibrating angle.

In contrast, in Embodiment 1, as described above, the oscillating plate 20 includes the first layer 101 and the second layer 102, the first layer 101 is made of silicon (Si), and the second layer 102 is made of scandium fluoride (ScF₃). Here, the linear expansion coefficient of silicon (Si) has a positive value, and the linear expansion coefficient of scandium fluoride (ScF₃) has a negative value. That is, the first layer 101 and the second layer 102 are made of materials having linear expansion coefficients with signs opposite to each other.

With this configuration, in Embodiment 1, variation of the resonance frequency of the oscillating plate 20 when the environmental temperature changes is suppressed. Hereinafter, this effect will be described.

First, a relationship between temperature change and resonance frequency will be described.

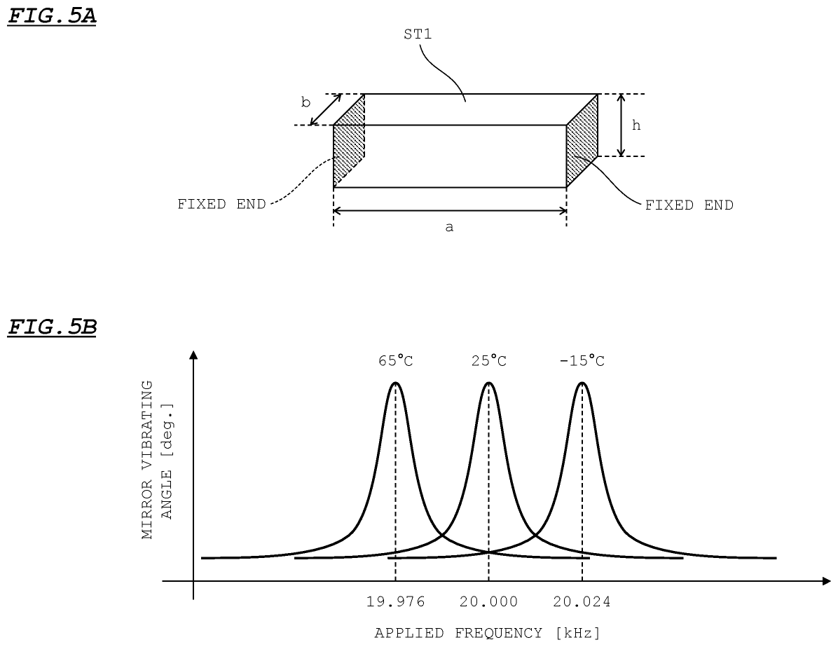

FIG. 5A is a perspective view schematically showing a configuration of a structure ST1 composed of a simple support beam (rectangular column).

The left and right end surfaces of the structure ST1

shown in FIG. 5A are fixed ends to be fixed to installation surfaces. The length in the lateral direction of the structure ST1 is denoted by a, the width in the depth direction of the structure ST1 is denoted by b, and the thickness of the structure ST1 is denoted by h. The Young's modulus of the structure ST1 is denoted by E, and the density of the structure ST1 is denoted by ρ.

In this case, a first-order resonance frequency F1 of the structure ST1 is represented by the following equation (1).

$$[ Math . 1 ]$$

$$F 1 = π \frac{h}{2 {a}^{2}} \times \sqrt{\frac{E}{12 ρ}} \qquad ( 1 )$$

As shown in the above equation (1), the resonance frequency of the structure ST1 is calculated by multiplying a dimension factor defined by “h/(2a²)” and a physical property factor defined by “E/(12ρ)”.

Here, when the temperature of the structure ST1 changes by ΔT, a length a2 and a thickness h2 of the structure ST1 are represented by the following equations (2-1) and (2-2).

a2=a+a×linear expansion coefficient×ΔT (2-1)

h2=h+h×linear expansion coefficient×ΔT (2-2)

Meanwhile, silicon (Si) described above has a positive linear expansion coefficient. Specifically, the linear expansion coefficient of silicon is 3 ppm/K. When the linear expansion coefficient is positive, the volume of the material increases with temperature rise. Therefore, in the case where the structure ST1 in FIG. 5A is made of only silicon, the length a and the thickness h in the above equation (1), which defines the resonance frequency of the structure ST1, increase with temperature rise, as seen also from the above equations (2-1) and (2-2).

When the volume of silicon increases as described above, the unit lattice (interatomic distance) of silicon widens. Therefore, in the case where the structure ST1 is made of only silicon, the density ρ in the above equation (1), which defines the resonance frequency of the structure ST1, decreases with temperature rise, and the Young's modulus E of the structure ST1 also decreases with temperature rise. The temperature coefficient of the density ρ of silicon is −9 ppm/K, and the temperature coefficient of the Young's modulus E of silicon is −60 ppm/K.

As described above, the length a, the thickness h, the density ρ, and the Young's modulus E in the above equation (1) change with temperature change. Therefore, as can be seen from the above equation (1), the resonance frequency of the structure ST1 also changes with temperature change. In the case where the structure ST1 is made of only silicon, the resonance frequency of the structure ST1 decreases with a rise in the temperature of the structure ST1 from the above equation (1).

Therefore, in the drive element 1 shown in FIG. 1, in the case where the oscillating plate 20 is formed from only silicon, the resonance frequency of the oscillating plate 20 decreases as the temperature of the oscillating plate 20 rises due to a rise in the environmental temperature, and increases as the temperature of the oscillating plate 20 decreases due to a decrease in the environmental temperature.

FIG. 5B is a graph showing a relationship between the frequency of a drive voltage and the vibrating angle of the mirror 40 in the case where the oscillating plate 20 is made of only silicon. In FIG. 5B, the frequency at which a maximum vibrating angle is reached at each temperature was calculated by the inventor.

When the oscillating plate 20 is made of only silicon, the resonance frequency of the oscillating plate 20 varies with temperature change as described with reference to the above equation (1). For example, when the case where the temperature of the oscillating plate 20 is 25° C. is used as a reference, the resonance frequency of the oscillating plate 20 at this time is 20 kHz as shown in FIG. 5B.

In contrast, when the temperature of the oscillating plate 20 decreases to −15° C., the resonance frequency of the oscillating plate 20 increases to 20.024 kHz, and when the temperature of the oscillating plate 20 rises to 65° C., the resonance frequency of the oscillating plate 20 decreases to 19.976 kHz. Therefore, in a state where the temperature of the oscillating plate 20 changes from 25° C., if a drive voltage is applied to the drive part 31 at a resonance frequency of 20 kHz which is the resonance frequency when the temperature of the oscillating plate 20 is 25° C., the vibrating angle of the mirror 40 becomes significantly smaller.

In contrast, in Embodiment 1, the oscillating plate 20 integrally includes not only the first layer 101 formed from silicon but also the second layer 102 formed from scandium fluoride.

Here, scandium fluoride forming the second layer 102 has a negative linear expansion coefficient. Specifically, the linear expansion coefficient of scandium fluoride is −15 ppm/K. When the linear expansion coefficient is negative, the volume of the material decreases with temperature rise. Therefore, both the density and the Young's modulus of the second layer 102 increase. The temperature coefficient of the density ρ of scandium fluoride is 45 ppm/K, and the temperature coefficient of the Young's modulus E of scandium fluoride is 800 ppm/K. Therefore, the dimension factor and the physical property factor in the above equation (1) for the second layer 102 oppose the dimension factor and the physical property factor of the first layer 101 made of silicon.

Therefore, when the temperature of the oscillating plate 20 changes, a change in resonance frequency due to the first layer 101 and a change in resonance frequency due to the second layer 102 act on the oscillating plate 20 in directions opposite to each other. More specifically, when the temperature of the oscillating plate 20 rises, an action of decreasing the resonance frequency by the first layer 101 works on the oscillating plate 20, and an action of increasing the resonance frequency by the second layer 102 works on the oscillating plate 20. By these opposing actions, variation of the resonance frequency of the oscillating plate 20 due to temperature change is suppressed.

As described above, in the configuration of Embodiment 1, even when the temperature of the oscillating plate 20 changes, a change in the resonance frequency of the oscillating plate 20 as a whole is suppressed. Therefore, regardless of temperature change, the vibrating angle of the mirror 40 can be maintained at an appropriate state by applying the drive voltage to each drive part 31 in the same manner as in the reference case.

### Examination

Next, the inventor examined the optimal thicknesses of the first layer 101 and the second layer 102.

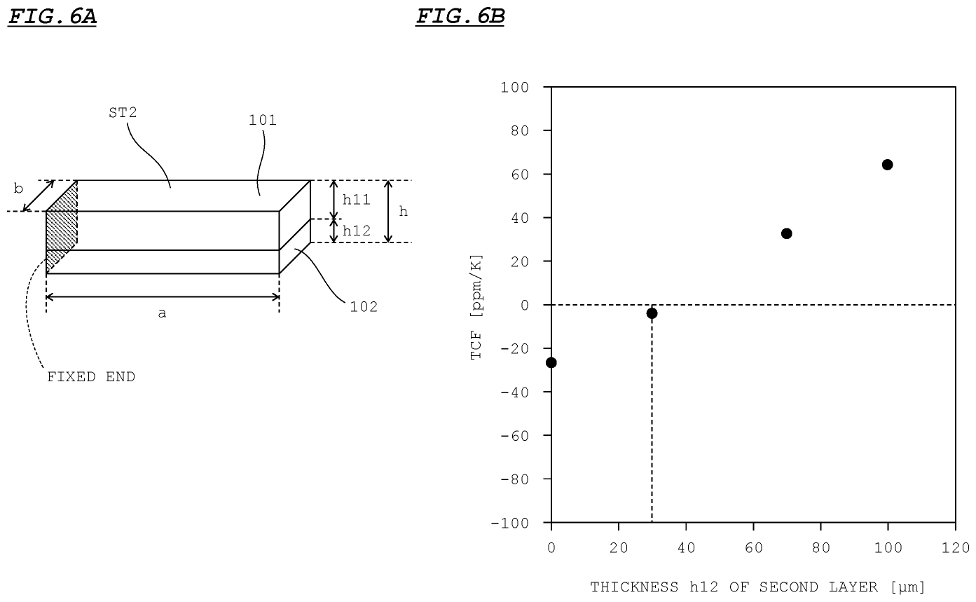

First, a preferred thickness of the second layer 102 in the case where the first layer 101 and the second layer 102 were applied to a structure ST2 composed of a cantilever beam shown in FIG. 6A was examined by simulation.

The structure ST2 is a structure in which the first layer 101 and the second layer 102 are stacked, and has a rectangular parallelepiped shape. The left end surface of the structure ST2 is a fixed end to be fixed to an installation surface. As in Embodiment 1, the first layer 101 is made of silicon, and the second layer 102 is made of scandium fluoride.

In the simulation, the length a in the longitudinal direction of the structure ST2 was set to 7000 μm, the width b in the depth direction of the structure ST2 was set to 1000 μm, and the thickness h of the structure ST2 was set to 500 μm. The thickness of the first layer 101 was denoted by h11, and the thickness of the second layer 102 was denoted by h12. A temperature coefficient TCF of the resonance frequency of the structure ST2 was calculated by varying the thickness h12 of the second layer 102.

FIG. 6B is a graph showing the simulation results.

In FIG. 6B, the horizontal axis indicates the thickness h12 (μm) of the second layer 102, and the vertical axis indicates the temperature coefficient TCF (ppm/K) of the resonance frequency of the structure ST2.

When the resonance frequency at the reference temperature is denoted by F0, the change in the temperature from the reference temperature is denoted by ΔT, and the temperature coefficient of the resonance frequency is denoted by TCF, the resonance frequency F1 of the structure ST2 is calculated by the following equation (3).

F1=F0+F0×TCF×ΔT (3)

From the above equation (3), it is found that, in order to suppress variation of the resonance frequency F1 when temperature change occurs, it is preferable that the temperature coefficient TCF of the resonance frequency is close to 0.

Referring to the graph in FIG. 6B, when the thickness h12 of the second layer 102 was about 30 μm, the value of the temperature coefficient TCF of the resonance frequency became almost 0. Therefore, it can be said that, in the structure ST2 shown in FIG. 6A, it is preferable that the thickness h12 of the second layer 102 is set to about 30 μm. In this case, since the value of the temperature coefficient TCF of the resonance frequency can be made almost 0, even if temperature change occurs in the structure ST2, the resonance frequency of the structure ST2 can be kept almost constant.

From this examination, it is found that, even in the oscillating plate 20 shown in FIG. 1, there is a preferred range of the thickness of the second layer 102 where the value of the temperature coefficient TCF of the resonance frequency of the oscillating plate 20 can be made close to 0.

However, the structure ST2 shown in FIG. 6A has a simple configuration composed of a cantilever beam, which is very different from the configuration of the oscillating plate 20 shown in FIG. 1. Therefore, it can be assumed that the preferred range (range around 30 μm) of the thickness of the second layer 102 obtained from the simulation results in FIG. 6B cannot be directly applied to the oscillating plate 20 in FIG. 1.

Therefore, the inventor examined a parameter that can define preferred ranges of the thicknesses of the first layer 101 and the second layer 102 in the configuration in FIG. 1. Then, the inventor inferred that the ratio between a degree of contribution of the first layer 101 to the temperature characteristic of the resonance frequency of the oscillating plate 20 and a degree of contribution of the second layer 102 to the temperature characteristic of the resonance frequency of the oscillating plate 20 can be used as the parameter that can define the preferred ranges of the thicknesses of the first layer 101 and the second layer 102.

In other words, when the oscillating plate 20 is composed of a lamination structure of the first layer 101 made of silicon and the second layer 102 made of scandium fluoride, the temperature coefficient TCF of the resonance frequency of the oscillating plate 20 can be assumed to be influenced by the cross-sectional areas of the first layer 101 and the second layer 102 and the linear expansion coefficients and the Young's moduli of the first layer 101 and the second layer 102.

Here, the value of the linear expansion coefficient relates to the variation of the dimensions and the density of the oscillating plate 20 associated with temperature change in the above equation (1), and the value of the Young's modulus relates to the softness of the oscillating plate 20 associated with temperature change. Therefore, the linear expansion coefficient and the Young's modulus of the first layer 101 and the linear expansion coefficient and the Young's modulus of the second layer 102 can contribute to the temperature characteristic of the resonance frequency of the oscillating plate 20.

The cross-sectional areas of the first layer 101 and the second layer 102 relate to the ratio between the above contributions of the first layer 101 and the second layer 102 to the oscillating plate 20. That is, the larger the cross-sectional area of each layer is, the greater the above contribution of each layer to the oscillating plate 20 is.

Based on this concept, the influence of the first layer 101 and the second layer 102 on the temperature characteristic of the resonance frequency of the oscillating plate 20 can be specified as in the following equations (4-1) and (4-2) using the cross-sectional area, the linear expansion coefficient, and the Young's modulus of each layer.

C1=A1×(α1+β1) (4-1)

C2=A2×(α2+β2) (4-2)

The above equation (4-1) indicates a degree of contribution C1 of the first layer 101 (silicon) to the temperature characteristic of the resonance frequency of the oscillating plate 20, and the above equation (4-2) indicates a degree of contribution C2 of the second layer 102 (scandium fluoride) to the temperature characteristic of the resonance frequency of the oscillating plate 20. In the above equation (4-1), the linear expansion coefficient, the temperature coefficient of the Young's modulus, and the cross-sectional area of the first layer 101 are denoted by α1, β1, and A1, respectively. In the above equation (4-2), the linear expansion coefficient, the temperature coefficient of the Young's modulus, and the cross-sectional area of the second layer 102 are denoted by α2, β2, and A2, respectively.

As described above, the linear expansion coefficient α1 and the temperature coefficient β1 of the Young's modulus of the first layer 101 (silicon) and the linear expansion coefficient α2 and the temperature coefficient β2 of the Young's modulus of the second layer 102 (scandium fluoride) have opposite signs, so that the degree of contribution C1 of the first layer 101 and the degree of contribution C2 of the second layer 102 to the temperature characteristic of the resonance frequency of the oscillating plate 20 act in directions opposite to each other. Therefore, it is considered that the closer the ratio between the degree of contribution C1 and the degree of contribution C2 is to 1, the more the degrees of contribution in the directions opposite to each other are balanced, so that the temperature coefficient TCF of the resonance frequency of the oscillating plate 20 approaches 0, that is, the resonance frequency is less likely to change with temperature change.

In the following, the ratio between the degree of contribution C1 and the degree of contribution C2 is referred to as “material ratio R”. The material ratio R is calculated by the following equation (5).

R=|C2|/|C1| (5)

As shown in equations (4-1) and (4-2), the degrees of contribution C1 and C2 include only the cross-sectional areas A1 and A2 as the dimension factors of the respective layers. Therefore, the material ratio R in the equation (5) includes only the ratio between the cross-sectional areas A1 and A2 as a dimension factor. On the other hand, in the configuration in FIG. 1, the thicknesses of the first layer 101 and the second layer 102 in the oscillating plate 20 are constant over the entire range of the oscillating plate 20. Therefore, the ratio between the cross-sectional area of the first layer 101 and the cross-sectional area of the second layer 102 is constant over the entire range of the oscillating plate 20 in FIG. 1. Thus, for example, if a preferred range of the material ratio R where the temperature coefficient TCF of the resonance frequency approaches 0 is obtained for the structure ST2 shown in FIG. 6A, the preferred range of the material ratio R can also be similarly applied to the oscillating plate 20 in FIG. 1.

The inventor examined, by simulation, the temperature coefficient TCF of the resonance frequency when the material ratio R was changed.

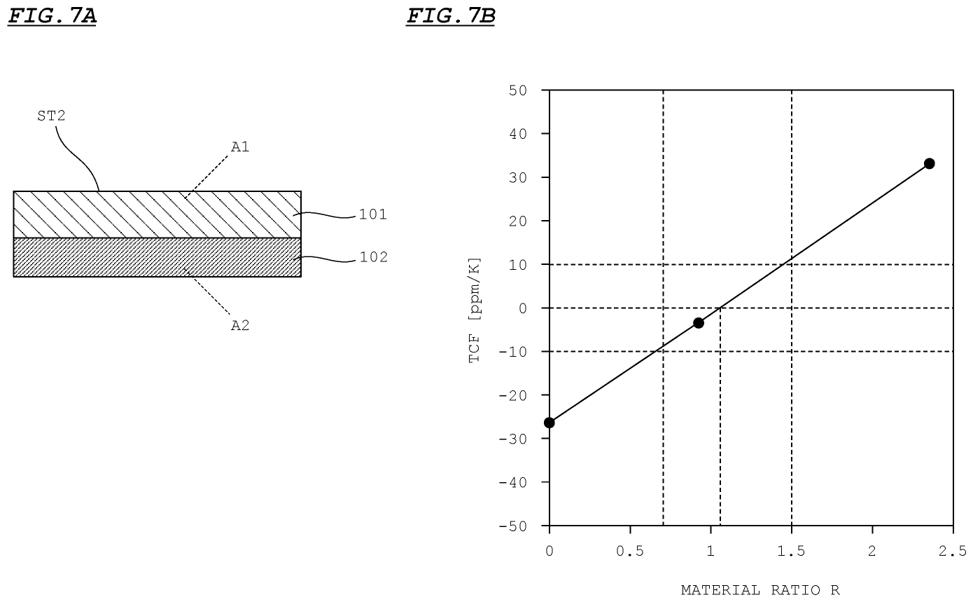

FIG. 7A is a cross-sectional view schematically showing a configuration of a structure ST2 composed of a cantilever beam, according to this simulation.

In this simulation, the structure ST2 was configured in the same manner as the structure ST2 shown in FIG. 6A, and the dimensions of each part of the structure ST2 were also set to be the same as in the case of FIG. 6A. FIG. 7A shows a cross-section of the structure ST2 in FIG. 6A, taken along a plane perpendicular to the direction of the length a. As in the simulation in FIG. 6A and FIG. 6B, the first layer 101 was made of silicon, and the second layer 102 was made of scandium fluoride. For the first layer 101 (silicon), the linear expansion coefficient α1 was 3 ppm/K, and the temperature coefficient β1 of the Young's modulus was −60 ppm/K. For the second layer 102 (scandium fluoride), the linear expansion coefficient α2 was −15 ppm/K, and the temperature coefficient β2 of the Young's modulus was 800 ppm/K.

In such a structure ST2, by changing the thickness of the first layer 101 and the thickness of the second layer 102, the cross-sectional area A1 of the first layer 101 and the cross-sectional area A2 of the second layer 102 were changed, thereby changing the material ratio R. For each of three material ratios R thus changed, the temperature coefficient TCF of the resonance frequency of the structure ST2 was calculated.

FIG. 7B is a graph showing the simulation results.

In FIG. 7B, the horizontal axis indicates the material ratio R obtained by dividing the absolute value of the degree of contribution C2 by the absolute value of the degree of contribution C1, and the vertical axis indicates the temperature coefficient TCF (ppm/K) of the resonance frequency. FIG. 7B shows a straight line obtained by connecting three measurement values, obtained by the simulation, with a solid line.

As shown in FIG. 7B, when the material ratio R is around 1, TCF is 0. In addition, when the material ratio R is not less than 0.7 and not greater than 1.5, TCF is not less than −10 ppm/K and not greater than 10 ppm/K. Therefore, by setting the ratio between the cross-sectional area A1 (thickness) of the first layer 101 and the cross-sectional area A2 (thickness) of the second layer 102 such that the material ratio R is within the range of not less than 0.7 and not greater than 1.5, the temperature coefficient TCF of the resonance frequency of the structure ST2 can be set to around 0, so that a change in the resonance frequency of the structure ST2 with respect to temperature change can be reduced to around 0. In order to more reliably set a change in the resonance frequency of the structure ST2 with respect to temperature change to around 0, it is preferable to set the material ratio R to around 1.

In the graph in FIG. 7B, in the case where the second layer 102 is not placed and the structure ST2 is composed of only the first layer 101, that is, when the material ratio R is zero, TCF is −27 ppm/K and is substantially equal to −30 ppm/K which is the normal TCF of silicon. Thus, it can be assumed that the graph in FIG. 7B substantially appropriately shows the relationship between the material ratio Rand TCF. From this, it is confirmed that the material ratio R used on the horizontal axis is appropriate as a parameter for evaluating the temperature coefficient TCF of the resonance frequency of the structure ST2.

As described above, the preferred range (not less than 0.7 and not greater than 1.5) of the material ratio R obtained in the simulation in FIG. 7B can also be similarly applied to the oscillating plate 20 in FIG. 1. Therefore, by setting the cross-sectional areas (thicknesses) of the first layer 101 and the second layer 102 such that the material ratio R is within this range in the oscillating plate 20 of the drive element 1 shown in FIG. 1, the temperature coefficient TCF of the resonance frequency of the drive element 1 can be made close to zero.

In the drive element 1 shown in FIG. 1, the rib for suppressing bending of the movable part 24 is provided on the surface on the Z-axis negative side of the movable part 24. Therefore, the cross-sectional area of the second layer 102 at the movable part 24 is different from the above cross-sectional area A2. However, a region corresponding to the rib is sufficiently small with respect to the entire oscillating plate 20, and thus, by applying the preferred range of the material ratio R to the entire oscillating plate 20 in FIG. 1 as described above, the temperature coefficient TCF of the resonance frequency of the drive element 1 can be made close to zero.

Next, the reason why it is preferable that the temperature coefficient TCF of the resonance frequency of the oscillating plate 20 is not less than −10 ppm/K and not greater than 10 ppm/K, will be described based on the simulation results in FIG. 7B.

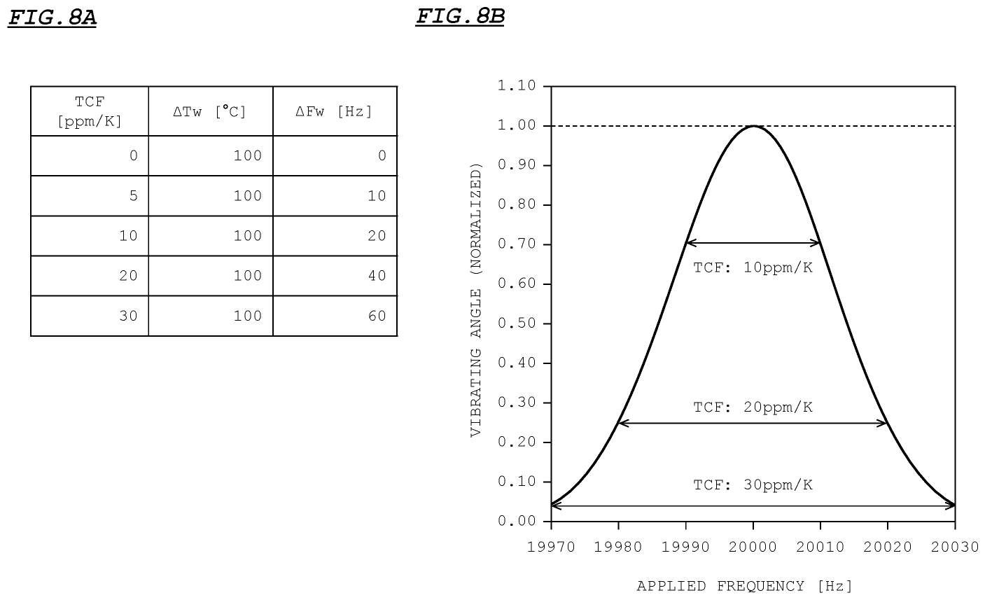

FIG. 8A is a diagram showing a relationship between the temperature coefficient TCF (ppm/K) of the resonance frequency of the oscillating plate 20, a temperature range ΔTw (° C.) of the oscillating plate 20, and a change width ΔFw (Hz) of the resonance frequency of the oscillating plate 20.

The relationship in FIG. 8A is for the case where the resonance frequency at the reference temperature (25° C.) is 20 kHz. The temperature range ΔTw is a positive and negative temperature range centered on the reference temperature (25° C.), and the change width ΔFw is a change width of the resonance frequency centered on 20 kHz. The temperature range ΔTw has the same positive and negative widths with the reference temperature (25° C.) as a center. For example, a range where a temperature range ΔTw is 100° C. is a range of ±50° C. with respect to the reference temperature (25° C.). The change width ΔFw has the same positive and negative widths with 20 kHz as a center. For example, a range where the change width ΔFw is 20 Hz is a range of ±10 Hz with respect to 20 kHz. The positive and negative widths of the change width ΔFw are calculated by a calculation expression (F0×TCF×ΔT) which is the second term of the right side of the above equation (3).

As shown in FIG. 8A, as the temperature coefficient TCF of the resonance frequency of the oscillating plate 20 increases, the change width ΔFw of the resonance frequency of the oscillating plate 20 also increases. For example, when the temperature coefficient TCF of the resonance frequency is 10 ppm/K, the change width ΔFw of the resonance frequency is 20 Hz; when the temperature coefficient TCF of the resonance frequency is 20 ppm/K, the change width ΔFw of the resonance frequency is 40 Hz; and when the temperature coefficient TCF of the resonance frequency is 30 ppm/K, the change width ΔFw of the resonance frequency is 60 Hz.

FIG. 8B is a graph showing a relationship between the frequency of a drive voltage and the vibrating angle of the mirror 40.

In FIG. 8B, the horizontal axis indicates the frequency (Hz) of a drive voltage applied to each drive part 31 installed on the oscillating plate 20. The vibrating angle on the vertical axis is a value normalized based on the maximum vibrating angle. When the temperature of the oscillating plate 20 is 25° C. which is the reference temperature, the resonance frequency of the oscillating plate 20 and the mirror 40 is 20 kHz which is a reference value. At this time, if the frequency of the drive voltage applied to each drive part 31 is 20 kHz, the vibrating angle of the mirror 40 becomes maximum.

If the resonance frequency of the oscillating plate 20 changes as the temperature of the oscillating plate 20 changes from 25° C. which is the reference temperature, even when a drive voltage of 20 kHz is applied to each drive part 31, the vibrating angle decreases from the maximum value. For example, when the temperature coefficient TCF of the resonance frequency is 10 ppm/K, the change width ΔFw of the resonance frequency is 20 Hz as shown in FIG. 8A, so that the vibrating angle decreases to about 0.7 times the maximum value as shown in FIG. 8B. In this case, to increase the vibrating angle to the same level as the maximum value, the maximum value of the drive voltage applied to each drive part 31 needs to be increased by about 1/0.7=1.4 times.

In the case of such a resonant type drive element, the maximum value of the drive voltage applied to each drive part 31 is ½ or less of that in a non-resonant type drive element. Thus, if the maximum value of the drive voltage applied to each drive part 31 is within 2 times, application of an excessive voltage to each drive part 31 can be avoided, so that the reliability of each drive part 31 can be maintained.

As described above, if the temperature coefficient TCF of the resonance frequency of the oscillating plate 20 is not greater than 10 ppm/K, the maximum value of the drive voltage applied to each drive part 31 can be reduced to about 1.4 times.

Therefore, by setting the temperature coefficient TCF of the resonance frequency of the oscillating plate 20 to be not greater than 10 ppm/K, application of an excessive voltage to each drive part 31 can be avoided.

Similarly, even when the temperature coefficient TCF of the resonance frequency of the oscillating plate 20 has a negative value, if the temperature coefficient TCF is not less than −10 ppm/K, the decrease in the vibrating angle can be reduced to about 0.7 times the maximum value, as in FIG. 8B. Therefore, by setting the temperature coefficient TCF of the resonance frequency of the oscillating plate 20 to be not greater than 10 ppm/K, the maximum value of the drive voltage applied to each drive part 31 can be reduced to about 1.4 times, so that application of an excessive voltage to each drive part 31 can be avoided.

Referring back to FIG. 7B, when TCF is not less than −10 ppm/K and not greater than 10 ppm/K, the material ratio R is not less than 0.7 and not greater than 1.5. Therefore, by selecting the material of the first layer 101 and the material of the second layer 102 and setting the cross-sectional area A1 (thickness) of the first layer 101 and the cross-sectional area A2 (thickness) of the second layer 102 such that the material ratio R is not less than 0.7 and not greater than 1.5, variation of the resonance frequency of the oscillating plate 20 can be suppressed, and the vibrating angle of the mirror 40 can be maintained high without applying an excessive voltage to each drive part 31.

In the simulation in FIG. 7A and FIG. 7B, of the two materials respectively forming the two layers included in the structure ST2 in FIG. 7A, the material having a positive linear expansion coefficient was silicon, and the material having a negative linear expansion coefficient was scandium fluoride. However, even if these two materials are other materials, the temperature coefficient TCF of the resonance frequency of the structure ST2 can be made close to zero by setting the material of each layer and the ratio between the cross-sectional areas of these two layers such that the material ratio R is within the above range. Therefore, also, for the two layers included in the oscillating plate 20 of the drive element 1, by setting the material of each layer and the ratio between the cross-sectional areas of these two layers such that the material ratio R of these two layers is within the above range, the temperature coefficient TCF of the resonance frequency of the drive element 1 can be made close to zero.

For example, the first layer 101 may be made of silicon (Si), and the second layer 102 may be made of a material composed mainly of scandium fluoride (ScF₃). In this case, at least one or more of yttria (Y), magnesium (Mg), barium (Ba), and zinc (Zn) may be added to scandium fluoride (ScF₃) such that Sc is replaced. The second layer 102 may be made of zirconium tungstate, or may be made of a material composed mainly of zirconium tungstate. In this case as well, by setting the material of each layer and the ratio between the cross-sectional areas of these two layers such that the material ratio R of these two layers is within the above range, the temperature coefficient TCF of the resonance frequency of the drive element 1 can be made close to zero.

When the oscillating plate 20 is configured as described above, warpage of the oscillating plate 20 associated with temperature change can also be suppressed.

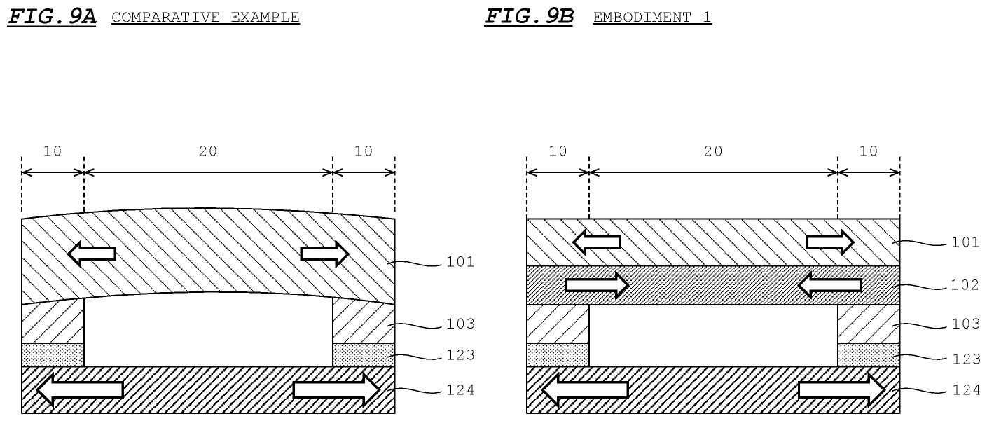

FIG. 9A and FIG. 9B are diagrams schematically showing cross-sections of the oscillating plates 20 and the fixing parts 10 in a comparative example and Embodiment 1, respectively. FIG. 9A and FIG. 9B each show a state where the lower surface of each fixing part 10 (the lower surface of each fixing layer 103) is installed on a package substrate 124 with an adhesive 123 therebetween. In the comparative example, the oscillating plate 20 and the fixing parts 10 are made of only silicon.

In the case of the comparative example, when the environmental temperature rises, the package substrate 124 and the first layer 101 expand due to thermal stress as shown in FIG. 9A. At this time, the package substrate 124 changes more greatly than the first layer 101, thereby causing the first layer 101 to warp convexly in the upward direction.

In contrast, in the case of Embodiment 1, as shown in FIG. 9B, when the environmental temperature rises, thermal stress in the direction of expansion is generated in the package substrate 124 and the first layer 101, and thermal stress in the direction of contraction is generated in the second layer 102. Accordingly, the action of upwardly convex warpage occurring in the package substrate 124 and the first layer 101 having a positive linear expansion coefficient and the action of downwardly convex warpage occurring in the second layer 102 having a negative linear expansion coefficient work on the oscillating plate 20. By these two opposing actions, warpage of the oscillating plate 20 is suppressed. Thus, in the configuration of Embodiment 1, when the environmental temperature changes, expansion and contraction are balanced in the first layer 101, the second layer 102, and the package substrate 124. Accordingly, deformation of the oscillating plate 20 due to temperature change is suppressed.

### Effects of Embodiment 1

According to Embodiment 1, the following effects are achieved.

The oscillating plate 20 contains a first material having a positive linear expansion coefficient (e.g., silicon) and a second material having a negative linear expansion coefficient (e.g., scandium fluoride). Since the signs of the linear expansion coefficients of the first material and the second material are opposite to each other as described above, when the environmental temperature around the drive element 1 changes, a change in the resonance frequency of the oscillating plate 20 due to the first material and a change in the resonance frequency of the oscillating plate 20 due to the second material act on the oscillating plate 20 in directions opposite to each other. Therefore, by these opposing actions, variation of the resonance frequency of the entire oscillating plate 20 is suppressed. Accordingly, variation of the resonance frequency of the drive element 1 due to temperature change can be suppressed.

The sign of the temperature coefficient of the Young's modulus of the first material having a positive linear expansion coefficient and contained in the oscillating plate 20 and the sign of the temperature coefficient of the Young's modulus of the second material having a negative linear expansion coefficient and contained in the oscillating plate 20 are opposite to each other. When the signs of the temperature coefficients of the Young's moduli of the first material and the second material are opposite to each other as described above, a change in resonance frequency due to the first material and a change in resonance frequency due to the second material act on the oscillating plate 20 in opposite directions from the above equation (1), so that deformation of the oscillating plate 20 due to temperature change is suppressed as in the above. Accordingly, variation of the resonance frequency of the drive element 1 due to temperature change can be suppressed.

The oscillating plate 20 includes the first layer 101 made of the first material having a positive linear expansion coefficient and the second layer 102 made of the second material having a negative linear expansion coefficient. With this configuration, variation of the resonance frequency of the oscillating plate 20 due to temperature change can be suppressed by a simple configuration in which two layers respectively formed from materials having linear expansion coefficients whose signs are different from each other are placed.

The degree of contribution C1 of the first material (first layer 101) to the temperature coefficient TCF of the resonance frequency of the oscillating plate 20 is defined by the above equation (4-1), and the degree of contribution C2 of the second material (second layer 102) to the temperature coefficient TCF of the resonance frequency of the oscillating plate 20 is defined by the above equation (4-2). The material ratio R is calculated by the above formula (5). As described with reference to FIG. 7A to FIG. 8B, the material ratio R is set to 0.7 to 1.5. Accordingly, as described with reference to FIG. 7B, the temperature coefficient TCF of the resonance frequency of the oscillating plate 20 is limited to the range of −10 ppm/K to +10 ppm/K. Therefore, while application of an excessive voltage to each drive part 31 is avoided, variation of the resonance frequency of the oscillating plate 20 due to temperature change can be effectively suppressed, so that the movable part 24 and the mirror 40 can be driven appropriately.

### Modification 1 of Embodiment 1

In Embodiment 1 above, the oscillating plate 20 is configured by stacking the first layer 101 made of a material having a positive linear expansion coefficient and the second layer 102 made of a material having a negative linear expansion coefficient. However, the present invention is not limited thereto, and the oscillating plate 20 may be composed of a composite layer in which a material having a positive linear expansion coefficient and a material having a negative linear expansion coefficient are mixed.

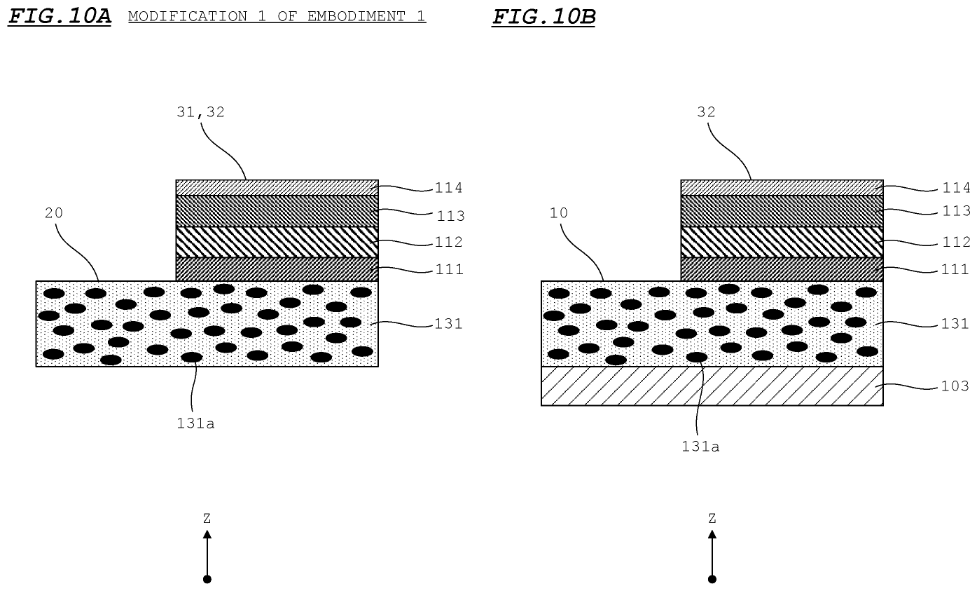

FIG. 10A is a diagram schematically showing a cross-section of a lamination structure composed of an oscillating plate 20 and a drive part 31 or a wiring part 32 according to Modification 1 of Embodiment 1.

The oscillating plate 20 is composed of a composite layer 131. The composite layer 131 is configured by mixing a resin having a positive linear expansion coefficient (e.g., an epoxy resin, a polyimide resin, or the like) with a filler 131a which is scandium fluoride having a negative linear expansion coefficient.

The material having a positive linear expansion coefficient and contained in the composite layer 131 may be silicon (Si). The filler 131a only needs to be made of a material having a negative linear expansion coefficient. For example, the filler 131a may be made of a material composed mainly of scandium fluoride (ScF₃). In this case, at least one or more of yttria (Y), magnesium (Mg), barium (Ba), and zinc (Zn) may be added to scandium fluoride (ScF₃) such that Sc is replaced. The filler 131a may be composed of zirconium tungstate, or may be made of a material composed mainly of zirconium tungstate.

The drive part 31 and the wiring part 32 have the same lamination structure as each other and are formed integrally. The drive part 31 and the wiring part 32 are placed on the surface on the Z-axis positive side of the oscillating plate 20. In the drive part 31 and the wiring part 32, a lower electrode 111, a piezoelectric layer 112, and upper electrodes 113 and 114 are formed in this order in the Z-axis positive direction. The lower electrode 111, the piezoelectric layer 112, and the upper electrode 113 are the same as in Embodiment 1. The upper electrode 114 is made of gold (Au).

FIG. 10B is a diagram schematically showing a cross-section of a lamination structure composed of a fixing part 10 and the wiring part 32 according to Modification 1 of Embodiment 1.

The composite layer 131 shown in FIG. 10A extends to the fixing part 10. That is, the composite layer 131 is integrally formed in the entire fixing part 10 and the entire oscillating plate 20. The fixing part 10 further includes a fixing layer 103 placed on the surface on the Z-axis negative side of the composite layer 131. The fixing layer 103 is made of silicon (Si), for example.

The wiring part 32 shown in FIG. 10A extends to the fixing part 10. That is, the wiring part 32 on the fixing part 10 and the wiring part 32 on the oscillating plate 20 are integrally formed.

In the fixing part 10, for example, when the lower electrode 111 of the wiring part 32 is connected to a ground, and a drive voltage is applied to the upper electrode 114 of the wiring part 32, the piezoelectric layer 112 of the drive part 31 connected to the wiring part 32 becomes deformed. Accordingly, the oscillating plate 20 is driven, and the movable part 24 and the mirror 40 (see FIG. 1) rotate about the rotation axis R10.

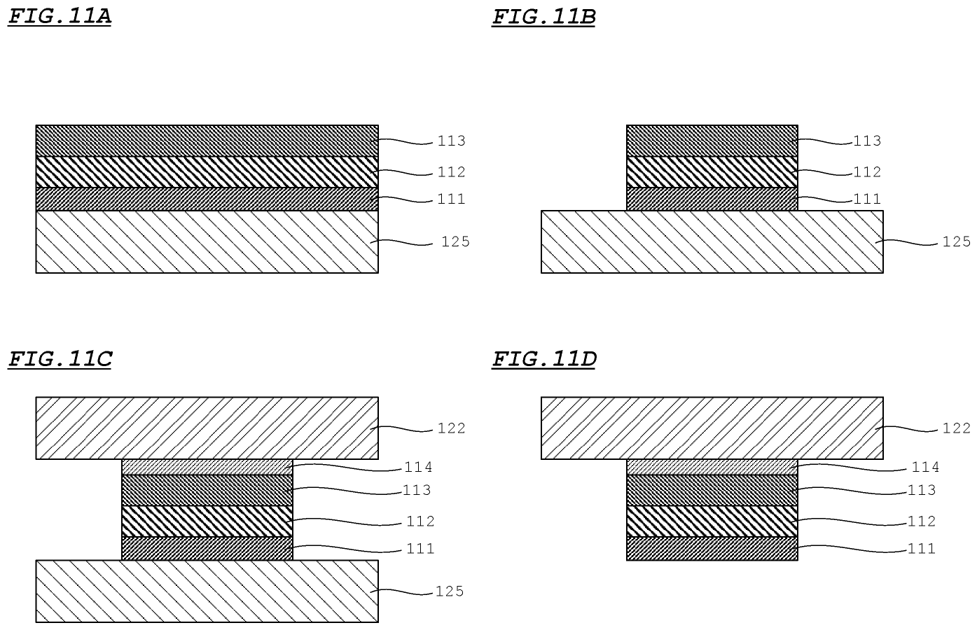

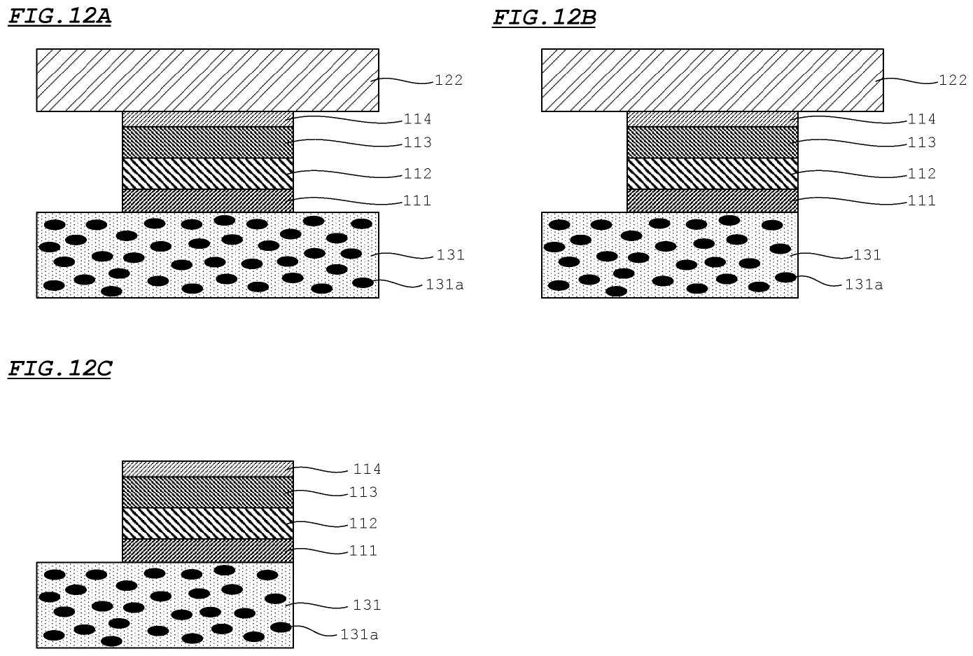

Next, a procedure for forming the drive element 1 according to Modification 1 of Embodiment 1 will be described with reference to cross-sectional views in FIG. 11A to FIG. 12C.

As shown in FIG. 11A, the lower electrode 111 (Pt), the piezoelectric layer 112 (PZT), and the upper electrode 113 (Au) are formed in this order by sputtering on the upper surface of a support substrate 125 made of silicon (Si).

Subsequently, as shown in FIG. 11B, the lower electrode 111, the piezoelectric layer 112, and the upper electrode 113 are removed by etching such that the lower electrode 111, the piezoelectric layer 112, and the upper electrode 113 remain in a region corresponding to each drive part 31 and each wiring part 32.

Subsequently, as shown in FIG. 11C, a support substrate 122 made of silicon (Si) is installed on the upper surface of the upper electrode 113 with the upper electrode 114 (Au) therebetween.

Subsequently, as shown in FIG. 11D, the support substrate 125 is removed.

Subsequently, as shown in FIG. 12A, the composite layer 131 is attached to the lower surface of the lower electrode 111. The composite layer 131 is formed by performing irradiation with light and a developing process using a semiconductor photolithography process on a material obtained by mixing a photosensitive resin (e.g., an epoxy resin, a polyimide resin, or the like) with the filler 131a in advance. The composite layer 131 is installed on the lower surface of the lower electrode 111, for example, by using a semiconductor photolithography process in a state where the composite layer 131 is placed on the lower surface of the lower electrode 111.

Subsequently, as shown in FIG. 12B, the composite layer 131 is removed by etching so as to have a desired shape. Accordingly, in a plan view, the shape of the composite layer 131 is made into a shape obtained by combining the fixing parts 10 and the oscillating plate 20 shown in FIG. 1.

Subsequently, as shown in FIG. 12C, the support substrate 122 is removed.

Thereafter, the fixing layer 103 is attached to the lower surface of the composite layer 131 corresponding to each fixing part 10. In addition, a rib, made of silicon (Si), for maintaining the strength of the movable part 24 is installed on the lower surface of the composite layer 131 corresponding to the movable part 24, and the mirror 40 is placed on the upper surface of the composite layer 131 corresponding to the movable part 24. Thus, the drive element 1 is completed.

As described above, according to Modification 1 of Embodiment 1, the oscillating plate 20 includes the composite layer 131 in which the first material having a positive linear expansion coefficient (e.g., a resin such as an epoxy resin or a polyimide resin) and the second material having a negative linear expansion coefficient (e.g., scandium fluoride) are combined. Thus, as in Embodiment 1, when the environmental temperature around the drive element 1 changes, variation of the resonance frequency of the oscillating plate 20 can be suppressed by the opposing actions of the first material and the second material. Accordingly, variation of the resonance frequency of the drive element 1 due to temperature change can be suppressed, so that the movable part 24 and the mirror 40 can be driven appropriately.

In this modification as well, the above equations (4-1) and (4-2) are established. That is, the degree of contribution C1 of the first material to the temperature coefficient TCF of the resonance frequency of the oscillating plate 20 is defined by the above equation (4-1), and the degree of contribution C2 of the second material to the temperature coefficient TCF of the resonance frequency of the oscillating plate 20 is defined by the above equation (4-2). In this case, in the calculation equation (4-1) for the degree of contribution C1, the cross-sectional area A1 is the average cross-sectional area of the first material having a positive linear expansion coefficient in the composite layer 131. In the calculation equation (4-2) for the degree of contribution C2, the cross-sectional area A2 is the average cross-sectional area of the second material (filler 131a) having a negative linear expansion coefficient. Then, as in Embodiment 1, the material ratio R is calculated by the above equation (5). In this modification as well, the same simulation results as in FIG. 7B are obtained.

Therefore, in this modification as well, by setting the ratio between the average cross-sectional area A1 of the first material and the average cross-sectional area A2 of the second material such that the material ratio R is within the range of not less than 0.7 and not greater than 1.5, the temperature coefficient TCF of the resonance frequency of the oscillating plate 20 can be set to around 0, so that a change in the resonance frequency of the oscillating plate 20 with respect to temperature change can be reduced to around 0. In order to more reliably set a change in the resonance frequency of the oscillating plate 20 with respect to temperature change to around 0, it is preferable to set the material ratio R to around 1.

### Modification 2 of Embodiment 1

In Embodiment 1 above, a detection part may be installed on each arm part 21 in addition to the drive part 31.

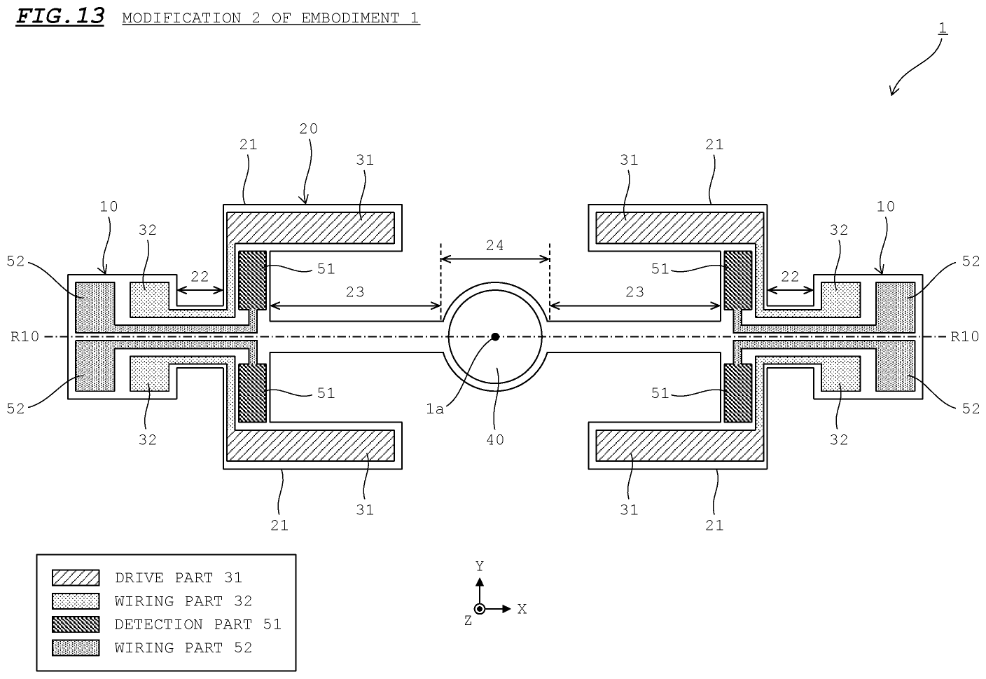

FIG. 13 is a plan view schematically showing a configuration of a drive element 1 according to Modification 2 of Embodiment 1.

Compared to Embodiment 1, the drive element 1 further includes four detection parts 51 and four wiring parts 52. The four detection parts 51 detect the drive state of the oscillating plate 20, and are placed on the surfaces on the Z-axis positive side of the portions, extending in the Y-axis direction, of the four arm parts 21, respectively. The four wiring parts 52 are placed on the surfaces on the Z-axis positive side of the oscillating plate 20 and the fixing parts 10. An end portion on the inner side (center 1a side) of each wiring part 52 is connected to the detection part 51, and an end portion on the outer side of each wiring part 52 is connected to an external circuit or the like at the fixing part 10. Each detection part 51 and each wiring part 52 are integrally formed and have the same lamination structure as the drive part 31 and the wiring part 32. The oscillating plate 20 has the same configuration as in Embodiment 1 or Modification 1 of Embodiment 1.

When the oscillating plate 20 is driven, each arm part 21 having an L-shape is repeatedly driven in the Z-axis direction. At this time, each detection part 51 expands and contracts in accordance with the drive state of each arm part 21, whereby a current flows from the detection part 51 via the wiring part 52 to the external circuit due to a piezoelectric effect. Accordingly, the drive state of the arm part 21 can be detected by referring to the current flowing to the external circuit.

### Embodiment 2

In Embodiment 1 above, the oscillating plate 20 has a tuning fork shape. However, in Embodiment 2, an oscillating plate has a meander shape.

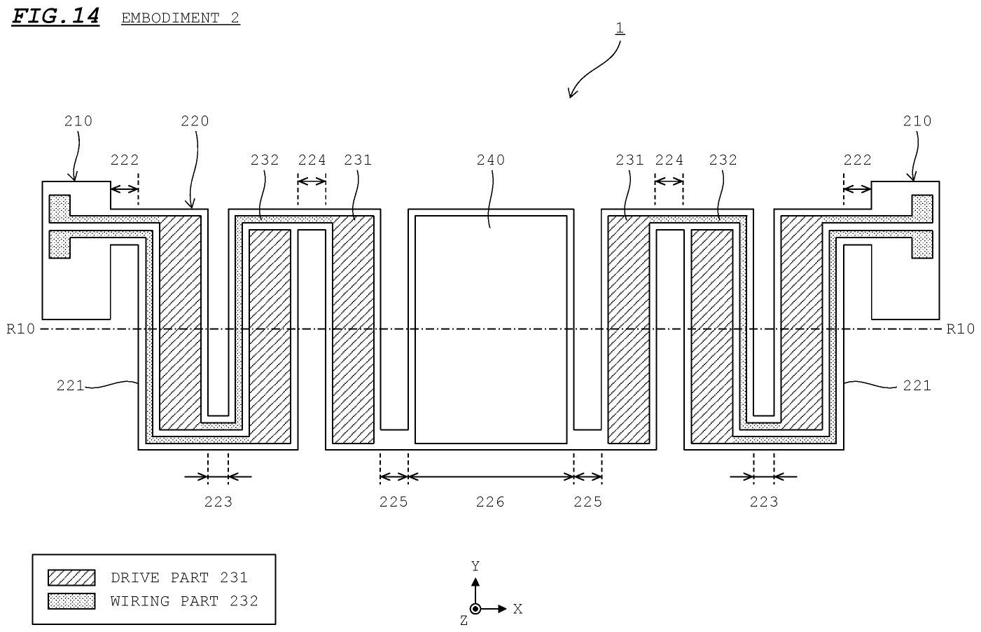

FIG. 14 is a plan view schematically showing a configuration of a drive element 1 according to Embodiment 2.

The drive element 1 includes a pair of fixing parts 210, an oscillating plate 220, six drive parts 231, six wiring parts 232, and a mirror 240. The drive element 1 is configured to be symmetrical with respect to a straight line passing through the center of the mirror 240 and parallel to the Y-axis direction. A movable part 226 is provided at the center of the drive element 1, and the movable part 226 rotates about a rotation axis R10 extending in the X-axis direction.

The pair of fixing parts 210 are aligned in the X-axis direction. Each fixing part 210 has the same lamination structure as in Embodiment 1 or Modification 1 of Embodiment 1. When the drive element 1 is installed, the surface on the Z-axis negative side of each fixing part 210 (the surface on the Z-axis negative side of the fixing layer 103 in FIG. 2B or FIG. 10B) is installed on a package substrate or the like using an adhesive.

The oscillating plate 220 includes six arm parts 221, two connection parts 222, two connection parts 223, two connection parts 224, two connection parts 225, and the movable part 226. The oscillating plate 220 has a meander shape. That is, the portion of the oscillating plate 220 on the X-axis positive side from the movable part 226 has a meander shape in a plan view, and the portion of the oscillating plate 220 on the X-axis negative side from the movable part 226 has a meander shape in a plan view. These two meander shapes face each other in the X-axis direction, thereby defining the shape of the oscillating plate 220. In addition, the oscillating plate 220 has the same configuration as in Embodiment 1 or Modification 1 of Embodiment 1.

Each arm part 221 has a rectangular shape that is long in the Y-axis direction in a plan view. Each outermost arm part 221 with respect to the movable part 226 is connected to the fixing part 210 by the connection part 222. Each innermost arm part 221 with respect to the movable part 226 is connected to the movable part 226 by the connection part 225. The adjacent arm parts 221 are connected to each other by the connection parts 223 and 224. The connection parts 222 and 224 are connected to end portions on the Y-axis positive side of the arm parts 221, and the connection parts 223 and 225 are connected to end portions on the Y-axis negative side of the arm parts 221.

The mirror 240 is placed on the surface on the Z-axis positive side of the movable part 226. A rib (not shown) for suppressing bending of the movable part 226 is formed on the surface on the Z-axis negative side of the movable part 226.

Each drive part 231 has the same lamination structure as the drive part 31 of Embodiment 1 or Modification 1 of Embodiment 1. Each wiring part 232 has the same lamination structure as the wiring part 32 of Embodiment 1 or Modification 1 of Embodiment 1. In Embodiment 2 as well, the drive parts 231 and the wiring parts 232 are formed integrally.

The six drive parts 231 are placed on the surfaces on the Z-axis positive side of the six arm parts 221, respectively. Each drive part 231 is a so-called piezoelectric transducer. When a drive voltage is applied to each drive part 231, the arm part 221 on which the drive part 231 is placed is driven. The six wiring parts 232 are placed on the surfaces on the Z-axis positive side of the oscillating plate 220 and the fixing parts 210. The drive part 231 placed on each outermost arm part 221 with respect to the movable part 226 and the drive part 231 placed on each innermost arm part 221 with respect to the movable part 226 are connected to each other by the wiring part 232. Each outermost drive part 231 with respect to the movable part 226 and the middle drive part 231 between the movable part 226 and each fixing part 10 are connected to an external power source or the like at the fixing part 10 by the wiring parts 232, respectively. Each wiring part 232 supplies a drive voltage to the drive part 231.

When the oscillating plate 220 is driven, voltages having opposite phases are applied to the drive parts 231 on the outermost arm part 221 and the innermost arm part 221 (first arm part) with respect to the movable part 226 and the drive part 231 on the arm part 221 (second arm part) between these two arm parts 221, such that the first arm part and the second arm part vibrate in opposite directions in the Z-axis direction. In addition, voltages having the same phase are applied to the drive parts 231 on one set of first arm parts aligned in the X-axis direction, such that the one set of first arm parts vibrate in the same direction, and voltages having the same phase are applied to the drive parts 231 on one set of second arm parts aligned in the X-axis direction, such that the one set of second arm parts vibrate in the same direction. Accordingly, the movable part 226 and the mirror 240 rotate about the rotation axis R10, so that the direction of light incident on the mirror 240 is changed in accordance with the rotation angle of the mirror 240.

In Embodiment 2 as well, the oscillating plate 220 has the same lamination structure as in Embodiment 1 or Modification 1 of Embodiment 1. That is, the oscillating plate 220 contains a first material having a positive linear expansion coefficient (e.g., silicon) and a second material having a negative linear expansion coefficient (e.g., scandium fluoride). Accordingly, variation of the resonance frequency of the oscillating plate 20 can be suppressed as in Embodiment 1 and Modification 1 of Embodiment 1.

In Embodiment 2 as well, by setting the ratio between the cross-sectional area A1 of the first material having a positive linear expansion coefficient and the cross-sectional area A2 of the second material having a negative linear expansion coefficient such that the material ratio R is within the range of not less than 0.7 and not greater than 1.5, the temperature coefficient TCF of the resonance frequency of the oscillating plate 20 can be set to around 0, so that a change in the resonance frequency of the oscillating plate 20 with respect to temperature change can be reduced to around 0. In order to more reliably set a change in the resonance frequency of the oscillating plate 20 with respect to temperature change to around 0, it is preferable to set the material ratio R to around 1.

### Modification of Embodiment 2

In Embodiment 2 above, a detection part may be installed on each arm part 221 in addition to the drive part 231.

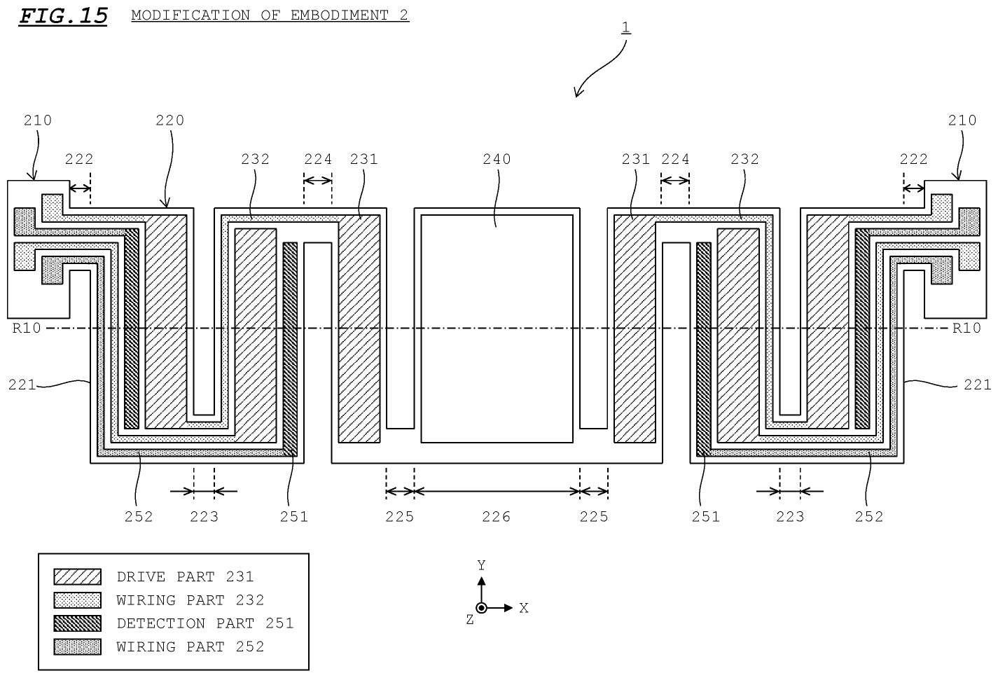

FIG. 15 is a plan view schematically showing a configuration of a drive element 1 according to a modification of Embodiment 2.

Compared to Embodiment 2, the drive element 1 further includes four detection parts 251 and four wiring parts 252. The four detection parts 251 detect the drive state of the oscillating plate 220. The four detection parts 251 are placed on the surfaces on the Z-axis positive side of the outermost arm parts 221 with respect to the movable part 226 and the middle arm parts 221 between the movable part 226 and the fixing parts 210. The four wiring parts 252 are placed on the surfaces on the Z-axis positive side of the oscillating plate 220 and the fixing parts 210. An end portion on the inner side of each wiring part 252 is connected to the detection part 251, and an end portion on the outer side of each wiring part 252 is connected to an external circuit or the like at the fixing part 210. Each detection part 251 and each wiring part 252 are integrally formed and have the same lamination structure as the drive part 231 and the wiring part 232. The oscillating plate 220 has the same configuration as in Embodiment 1 or Modification 1 of Embodiment 1.

When the oscillating plate 220 is driven, each arm part 221 is repeatedly driven in the Z-axis direction. At this time, each detection part 251 expands and contracts in accordance with the drive state of each arm part 221, whereby a current flows from the detection part 251 via the wiring part 252 to the external circuit due to a piezoelectric effect. Accordingly, the drive state of the arm part 221 can be detected by referring to the current flowing to the external circuit.

### Other Modifications

In Embodiment 1 and Modifications 1 and 2 of Embodiment 1, the first material contained in the oscillating plate 20 is made of a material having a positive linear expansion coefficient and a negative temperature coefficient of a Young's modulus (e.g., silicon), and the second material contained in the oscillating plate 20 is made of a material having a negative linear expansion coefficient and a positive temperature coefficient of a Young's modulus (e.g., scandium fluoride). However, the present invention is not limited thereto, and the signs of the linear expansion coefficients and the temperature coefficients of the Young's moduli of the first material and the second material are not limited to the above combination as long as, when the environmental temperature around the drive element 1 changes, a change in the resonance frequency of the oscillating plate 20 due to the first material and a change in the resonance frequency of the oscillating plate 20 due to the second material act on the oscillating plate 20 in directions opposite to each other. Similarly, in Embodiment 2 and the modification of Embodiment 2 as well, the signs of the linear expansion coefficients and the temperature coefficients of the Young's moduli of the first material and the second material are not limited to the above combination. In these cases as well, the linear expansion coefficient, the temperature coefficient of the Young's modulus, and the cross-sectional area of each material are preferably set such that the material ratio R is not less than 0.7 and not greater than 1.5.

In each of Embodiments 1 and 2 and the modifications of Embodiments 1 and 2, the fixing part 10 or 210 includes the fixing layer 103 on the lower surface side. However, the fixing layer 103 does not necessarily need to be provided, and may be omitted. In this case, the lower surface of the second layer 102 or the composite layer 131 corresponding to each fixing part 10 or 210 is installed on a package substrate or the like using an adhesive.

In Embodiment 1 and Modification 1 of Embodiment 1, the fixing layer 103 is made of silicon. However, the present invention is not limited thereto, and the fixing layer 103 may be made of a material other than silicon. For example, in Embodiment 1, the fixing layer 103 may be made of the same second material (scandium fluoride) as the second layer 102, and in Modification 1 of Embodiment 1, the fixing layer 103 may be made of the second material (scandium fluoride) of the filler 131a contained in the composite layer 131. Similarly, in Modification 2 of Embodiment 1, Embodiment 2, and the modification of Embodiment 2 as well, the fixing layer 103 may be made of a material other than silicon.

In Modification 1 of Embodiment 1, each drive part 31 and each wiring part 32 include the upper electrode 114 on the upper surface side. However, the upper electrode 113 only needs to be provided on the upper surface side of each drive part 31 and each wiring part 32, and the upper electrode 114 may be finally removed in the formation procedure in FIG. 11A to FIG. 12C.

In Modification 2 of Embodiment 1, each detection part 51 and each wiring part 52 are configured in the same manner as the drive part 31, and the drive state of each arm part 21 is detected by referring to a current generated by a piezoelectric effect. However, the present invention is not limited thereto, and a strain resistance effect in which resistance changes in response to deformation can also be used for detection by the detection part 51. In this case, for example, the detection part 51 is composed of a metal strain resistive element placed on the oscillating plate 20. Alternatively, the detection part 51 may be formed as a strain resistive element by altering the surface on the Z-axis positive side of silicon forming the oscillating plate 20 and having strain resistance in this portion. The wiring part 52 connected to the detection part 51 includes a wire for applying a voltage to the detection part 51 and a wire for detecting a resistance value of the detection part 51. The drive state of the arm part 21 can be detected by referring to the resistance value of the detection part 51. Similarly, in the modification of Embodiment 2 as well, each detection part 251 may be composed of a strain resistive element whose resistance changes in response to deformation.

In Embodiment 1 and Modifications 1 and 2 of Embodiment 1, one fixing part 10, two arm parts 21, a set of connection parts 22 and 23, two drive parts 31, and two wiring parts 32 are provided on each of the X-axis positive side and the X-axis negative side of the movable part 24. However, these components may be provided on only either the X-axis positive side or the X-axis negative side of the movable part 24. Similarly, in Embodiment 2 and the modification of Embodiment 2 as well, one fixing part 210, three arm parts 221, a set of connection parts 222 to 225, three drive parts 231, and three wiring parts 232 may be provided on only either the X-axis positive side or the X-axis negative side of the movable part 226.

In Embodiment 1 and Modifications 1 and 2 of Embodiment 1, the rib for suppressing bending of the movable part 24 is provided on the surface on the Z-axis negative side of the movable part 24. However, the rib does not necessarily have to be provided. In addition, in Embodiment 2 and the modification of Embodiment 2, the rib for suppressing bending of the movable part 226 is provided on the surface on the Z-axis negative side of the movable part 226, but this rib does not necessarily have to be provided.

In addition to the above, various modifications can be made as appropriate to the embodiments of the present invention, without departing from the scope of the technological idea defined by the claims.

What is claimed is:

1. A drive element comprising:
a fixing part;
an oscillating plate connected to the fixing part and having a movable part configured to rotate about a rotation axis; and
a drive part placed on the oscillating plate and configured to drive the oscillating plate, wherein
the oscillating plate contains a first material having a positive linear expansion coefficient and a second material having a negative linear expansion coefficient.

2. The drive element according to claim 1, wherein a sign of a temperature coefficient of a Young's modulus of the first material and a sign of a temperature coefficient of a Young's modulus of the second material are opposite to each other.

3. The drive element according to claim 1, wherein the oscillating plate includes a first layer made of the first material and a second layer made of the second material.

4. The drive element according to claim 1, wherein the oscillating plate includes a layer in which the first material and the second material are combined.

5. The drive element according to claim 3, wherein when, for the first material, the linear expansion coefficient is denoted by α1, the temperature coefficient of the Young's modulus is denoted by β1, a cross-sectional area is denoted by A1, and a degree of contribution C1 of the first material to a temperature characteristic of a resonance frequency of the oscillating plate is represented by the following equation (11), and for the second material, the linear expansion coefficient is denoted by α2, the temperature coefficient of the Young's modulus is denoted by β2, a cross-sectional area is denoted by A2, and a degree of contribution C2 of the second material to the temperature characteristic of the resonance frequency of the oscillating plate is represented by the following equation (12), a material ratio obtained by dividing an absolute value of the degree of contribution C2 by an absolute value of the degree of contribution C1 is set to be not less than 0.7 and not greater than 1.5,
C1=A1×(α1+β1) (11),
C2=A2×(α2+β2) (12).

6. The drive element according to claim 1, wherein the drive part is a piezoelectric transducer.

7. The drive element according to claim 1, wherein the oscillating plate has a tuning fork shape.

8. The drive element according to claim 1, wherein the oscillating plate has a meander shape.

9. The drive element according to claim 1, further comprising a detection part, placed on the oscillating plate, for detecting a drive state of the oscillating plate.

10. The drive element according to claim 1, wherein a mirror is placed on the movable part.
